(19) United States
(12) Patent Application Publication
(10) Pub. No.: US 2022/0413183 A1
(43) Pub. Date: Dec. 29, 2022

(54) DEVICE FOR PREVENTING RISK OF ATMOSPHERIC DISTURBANCES FOR AN AIRCRAFT IN THE AIR AND ON THE GROUND

(71) Applicant: SAFRAN ELECTRONICS & DEFENSE COCKPIT SOLUTIONS, Montreuil (FR)

(72) Inventor: Vincent MELCHOR, MOISSY-CRAMAYEL (FR)

(73) Assignee: SAFRAN ELECTRONICS & DEFENSE COCKPIT SOLUTIONS, Montreuil (FR)

(21) Appl. No.: 17/779,734

(22) PCT Filed: Nov. 1, 2020
(86) PCT No.: PCT/EP2020/084121

§ 371 Date: May 25, 2022

(30) Foreign Application Priority Data
Dec. 5, 2019 (FR) 1913801

(51) Int. Cl. G01W 1/02; G01R 29/08; B64D 45/02

(52) U.S. Cl. CPC G01W 1/02; G01R 29/0842; B64D 45/02

(57) ABSTRACT

A device for preventing, in real time, risk of atmospheric disturbance (DIS) for an aircraft in the air or on the ground includes acquisition means configured to acquire data corresponding to said risk. The device further includes design means configured to produce a predictive map of at least one critical area corresponding to at least one level of risk of disturbance that has been determined, and protection means (MP) configured to protect electronic components on board the aircraft which are liable to be damaged if the aircraft passes through said at least one critical area.

The present invention relates to aircraft and relates more particularly to the safety of passengers on board aircraft.

The densification of traffic is leading aircraft manufacturers to build lighter aircraft to reduce their energy consumption and carry more passengers.

In order to meet these needs while respecting safety standards, aircraft manufacturers choose to use light materials, for example based on carbon fibers.

Moreover, with the requirements of profitability and the imperatives of schedules for commercial flights, it becomes increasingly difficult to avoid atmospheric disturbances both on the ground, in particular during the reloading phases, and in the air.

The term “atmospheric disturbances” means any disruptor which may have adverse effects on the integrity of the equipment. For example, electromagnetic radiation from a lightning strike, cosmic or ionising radiation may be mentioned.

Thus, these atmospheric disturbances can endanger the safety of passengers on board the aircraft. Indeed, lightning strikes an aircraft on average twice a year, which can destroy the electronic components on board or lead to a random operation.

Even if an attempt is made to avoid them, the collection of information on the risk of exposure to these disturbances cannot be performed in flight. It is therefore difficult to predict the level of risk during the flight.

In order to reduce this risk, all electronic components of the aircraft are systematically protected, which does not allow a real mass gain.

In some types of commercial aircraft, for example, the mass of electronic components for filtering represents approximately 500 Kg.

In addition, in order to protect these components, transient voltage suppressor diodes are used and consequently multiply the mass by two.

This large mass is due to the use of composite materials. Indeed, the waveforms induced on the cables are more energetic than on aluminium aircraft.

Under these conditions, it becomes difficult to simultaneously meet economic requirements while preserving passenger safety.

There is therefore a need to use an automated system capable of limiting the risks of exposure of the aircraft in the air and on the ground depending on the environment in which it operates.

This more particularly leads to a reduction in the mass of the electronic components on board the aircraft.

In view of the foregoing, the invention proposes to overcome the aforementioned constraints by proposing a device for preventing the risk of atmospheric disturbances for an aircraft in the air or on the ground depending on the route taken and the atmospheric conditions around said aircraft.

The object of the invention is therefore, according to one first aspect, a method for preventing, in real time, risk of atmospheric disturbances for an aircraft in the air or on the ground, comprising at least one acquisition by the aircraft of data corresponding to said risks.

The method further comprises a development, from said data, of a predictive map of at least one critical area corresponding to at least one determined level of risk of disturbance, and an implementation of a protection of electronic components on board the aircraft which are liable to be damaged if the aircraft passes through said at least one critical area.

In other words, for each type of disturbance, a specific risk index is defined which allows optimising the implementation of the protection of electronic components, if the value of the risk index is high enough to qualify the area comprising this disturbance, as critical area.

Thus, depending on the type of atmospheric disturbance, it is possible to protect the components which are liable to be damaged if the aircraft is particularly exposed to this type of disturbance, for example lightning strike.

Advantageously, said at least one acquisition comprises a measurement, by the aircraft, of the electric field, the magnetic field, the electric and magnetic radio waves, and a remote reception of data for measuring the electric field, the magnetic field, the electric radio waves and the magnetic radio waves produced by at least two other aircraft in the air or on the ground and/or ground stations.

The magnetic radio waves, preferably medium waves having a frequency between 10 and 150 kHz, allow detecting the electric arcs at long distances.

The near electric field allows in particular determining whether there is a risk of lightning strike in the near field, unlike radio electric waves which allow a long distance detection.

It should be noted that the phase shift between the electric and magnetic fields allows determining, by correlating it with the time of the realization of the two measurements, the position of the atmospheric disturbance.

Preferably, the method comprises a remote storage, in real time, of the acquired data.

Each aircraft can thus share its position and the data relating to the risk of atmospheric disturbances, and thus develop a more accurate map.

Shared data can be correlated with information from ground stations.

Advantageously, the development of the predictive map comprises an implementation of at least one supervised or unsupervised deep learning machine.

The use of a deep learning machine allows efficiently sorting the data shared by aircraft in the air or on the ground, and the ground stations, and thus developing a specific risk index at each risk of atmospheric disturbance depending on the route taken by the aircraft.

Preferably, the implementation of the protection of the electronic components comprises a deactivation of said components and/or an activation of means for isolating said components.

In order to limit the risks of destruction or random operation of electronic components, it is advantageous to graduate the level of sensitivity of said components depending on the level of risk of the detected disturbance and thus choose to deactivate, isolate or maintain the operation of these components.

Preferably, the atmospheric disturbances comprise the lightning strike and/or an exposure to cosmic and/or ionising rays.

For example, an exposure to Gamma and/or Alpha and/or Beta and/or X rays may be mentioned.

According to another aspect, there is proposed a device for preventing, in real time, risk of atmospheric disturbances for an aircraft in the air or on the ground, comprising acquisition means capable of acquiring data corresponding to said risk.

It also includes design means capable of developing a predictive map of at least one critical area corresponding to at least one determined level of risk of disturbance, and protection means for protecting electronic components on board the aircraft which are liable to be damaged if the aircraft passes through said at least one critical area.

Advantageously, the acquisition means comprise measuring means capable of measuring the electric field, the magnetic field, the electric radio waves and the magnetic radio waves, and telecommunication means capable of receiving the data for measuring the electric field, the magnetic field, and the magnetic radio waves and the electric radio waves, these measurements being carried out by at least two other aircraft in the air or on the ground and/or ground stations.

May be mentioned as telecommunication means, the low orbit satellite constellations such as Iridium® and Starlink®, nanosatellites of the CubeSat® type or VHF (for “Very High Frequency”) or UHF (“Ultra High Frequency”) radios

Preferably, the acquisition means include at least one electro-optical sensor capable of measuring the near peripheral electric and magnetic field.

Advantageously, the device comprises means for remote storage, in real time, of the acquired data.

The data collected by the aircraft in the air or on the ground can be redirected to a remote computer server capable of storing said data and exploiting it.

Preferably, the design means comprise at least one supervised or unsupervised deep learning machine.

Preferably, the protection means comprise isolation means, the protection means being capable of deactivating said components and/or activating the means for isolating said components.

Some electronic components, generally used in intelligent and/or switching architectures, are particularly sensitive, such as the SSPC (for “Solid State Power Controllers”) and the contactors. They therefore easily change state, which can modify the operation or damage the other electronic components.

Among the isolation means, the active components of the transistor and thyristor type are particularly adapted against the strong and slow lightning strikes, for example between 70 and 120 μs.

For short lightning strikes, it is advantageous to use surge suppressors.

Advantageously, the atmospheric disturbances comprise the lightning strike and/or an exposure to cosmic and/or ionising rays.

Another subject of the invention is an aircraft comprising a device for preventing, in real time, risk of atmospheric disturbances as defined above.

Other aims, features and advantages of the invention will appear on reading the following description, given solely by way of non-limiting example, and made with reference to the appended drawings in which:

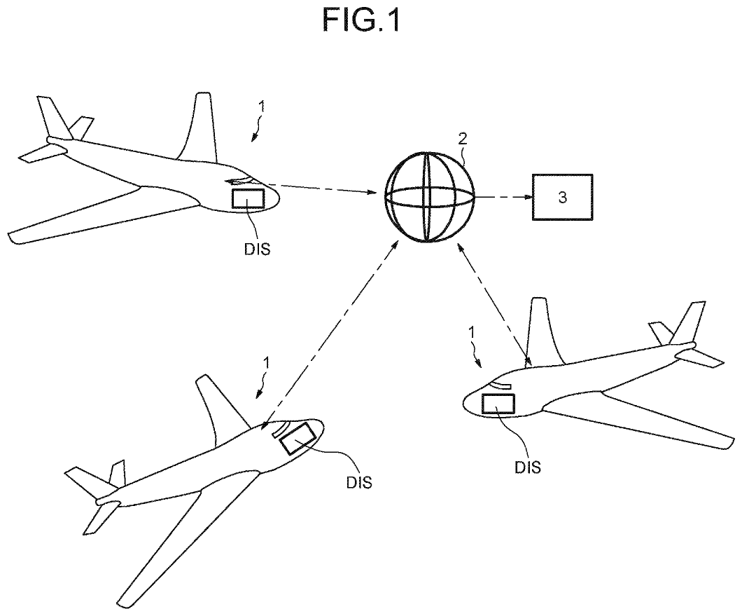

FIG. 1 represents a group of aircraft, each comprising a device for preventing, in real time, risk of atmospheric disturbances and;

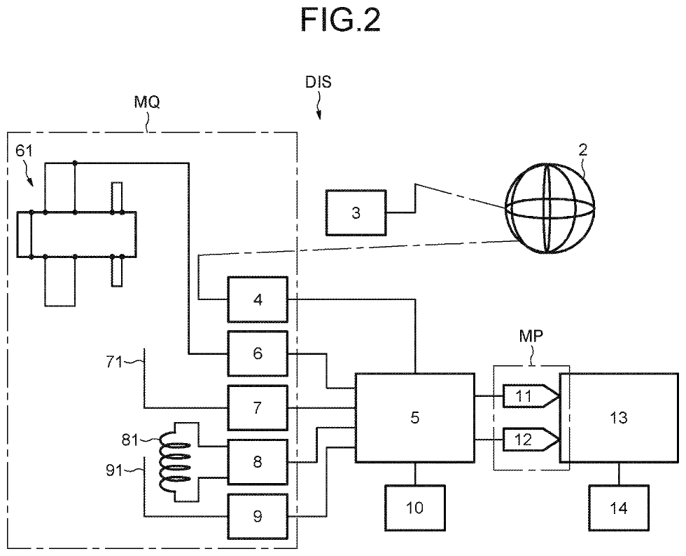

FIG. 2 illustrates the components of said prevention device.

In FIG. 1, a group of aircraft 1 is represented, each comprising a device for preventing, in real time, risk of atmospheric disturbances DIS, whose components will be detailed in FIG. 2;

The prevention device DIS is capable of acquiring data corresponding to said risks, but also of transmitting them to another aircraft 1 equipped with said device DIS, and this in order to develop a risk predictive map.

The risk map will be visible on a screen in the cockpit of the aircraft 1.

The data circulates between two aircraft 1 via nanosatellites or via satellite constellations 2 capable of traveling in low orbit.

The data can further be stored in a remote server 3.

Moreover, this remote server 3 can be consulted by any aircraft 1 comprising the device DIS or by any ground station having the authorisation to access it.

This data thus stored constitute a solid database capable of predicting with more accuracy the disturbances likely to be encountered on an air path.

These stored data will subsequently be correlated with data measured by acquisition means MQ on board the aircraft 1 illustrated in FIG. 2.

The acquisition means MQ are capable of acquiring data corresponding to at least one risk.

The prevention device DIS herein comprises first measuring means 6 capable of measuring the electric and magnetic fields near the aircraft 1.

The term “near” means a distance between 0 and 300 m from the aircraft in any direction.

The electric field allows detecting a risk of lightning strike in the near field, and the magnetic field, by its significant variations, the passage or the triggering of a discharge of several hundred amperes per meter.

In order to measure the electric field and the magnetic field, the first measuring means 6 is herein coupled to two optical fibres 61 capable of supplying electro-optical sensors which are not represented herein.

Moreover, it should be noted that when the electric field is measured, the Pockel effect electro-optical sensors are powered.

When the magnetic field is measured, the Faraday effect electro-optical sensors are powered.

The optical fibers 61 are further capable to be fixed on the facade of the aircraft 1.

For a better accuracy in the measurements, it is advantageous to fix the optical fibres 61 on the ends of the aircraft, for example at the end of the wings.

In order to detect the electric arcs at a long distance, the prevention device DIS further comprises second measuring means 7 capable of measuring medium electric radio waves having a frequency between 10 and 150 kHz.

Moreover, the second measuring means 7 can be coupled to a whip antenna 71, which is particularly advantageous for detecting the electric field produced by the electric arcs.

Third measuring means 8 allow measuring the average magnetic radio waves from the electric arcs and having a frequency between 10 and 150 kHz in order to detect, at long distance, the passage or the triggering of a discharge. It can for example be coupled to a loop type antenna 81.

Furthermore, in order to make the best use of the measured data, it is advantageous to obtain the exact positions of the atmospheric disturbances detected in order to place them on the predictive map.

To do this, the prevention device DIS comprises positioning means 9 capable of acquiring data relating to the position of the detected disturbance, in particular the altitude, the latitude and the time of said detection, and this via the Galileo constellation for example.

These measured data will subsequently be transmitted to design means 5 capable of generating the predictive map depending on this data.

The design means 5 also receive data measured by other aircraft 1 comprising said prevention device DIS, and this by initially requesting an access to the remote server 3 by telecommunication means 4.

By way of example, the telecommunication means 4 can be of the ADS-B (for “Automatic dependent surveillance-broadcast”) type.

These received data, initially stored in the remote server 3, comprise a plurality of physical quantities, for example the electric field, the magnetic field, the electric and magnetic radio waves and the positions of the different aircraft 1 in the air or on the ground during the detection of a risk of disturbance.

The design means 5 then develop the predictive map using, for example, a supervised or unsupervised deep learning machine.

The deep learning machine allows more accurately defining a critical area corresponding to a determined level of risk, and this for each of the risk of atmospheric disturbances for the aircraft 1 in the air or on the ground.

The processing of these data can also be carried out on the ground and retransmitted to the aircraft 1. This also allows the collected data to be correlated with the information on the ground and thus to increase the accuracy of the measurements.

The developed predictive map will be displayed on an all-screen dashboard 10.

The pilot of the aircraft 1 can thus make arrangements to avoid, protect or deactivate electronic components 14 which are liable to be damaged when the aircraft 1 passes through a critical area.

To do this, the prevention device DIS comprises protection means MP capable of deactivating or programming a subsequent deactivation of said electronic components 14.

In some cases, a portion of the electronic components is essential for the proper conduction of the trip. It is then necessary to isolate the components by isolation means which are not represented in the figure, in order to guarantee their optimal operation.

It should be noted that the deactivation and the isolation of the electronic components is done by the use of control means 11 and 12 capable of disconnecting or the couplings between said electronic components 14 and the electrical distribution system 13 or to isolate them.

Moreover, the invention is not limited to these embodiments and implementations but encompasses all variants thereof, for example the level of sensitivity of the electronic components can be graduated depending on the level of risk.

1. A method for preventing, in real time, risk of atmospheric disturbances for an aircraft in the air or on the ground, comprising:
at least one acquisition by the aircraft of data corresponding to said risks;
development, from said data, of a predictive map of at least one critical area corresponding to at least one determined level of risk of disturbance; and
implementation of a protection of electronic components on board the aircraft which are liable to be damaged if the aircraft passes through said at least one critical area.

2. The method according to claim 1, wherein said at least one acquisition comprises measurement, by the aircraft, of the electric field, the magnetic field, the electric and magnetic radio waves, and remote reception of data for measuring the electric field, the magnetic field, the electric radio waves and the magnetic radio waves produced by at least two other aircraft in the air or on the ground and/or ground stations.

3. The method according to claim 1, comprising remote storage, in real time, of the acquired data.

4. The method according to claim 1, wherein the development of the predictive map comprises implementation of at least one supervised or unsupervised deep learning machine.

5. The method according to claim 1, wherein implementation of the protection of the electronic components comprises deactivation of said components and/or activation of means for isolating said components.

6. The method according to claim 1, wherein the atmospheric disturbances comprise a lightning strike and/or an exposure to cosmic and/or ionising rays.

7. A device for preventing, in real time, risk of atmospheric disturbances (DIS) for an aircraft in the air or on the ground, comprising:
acquisition means (MQ) capable of acquiring data corresponding to said risk;
design means configured to develop a predictive map of at least one critical area corresponding to at least one determined level of risk of disturbance; and
protection means (MP) configured to protect electronic components on board the aircraft which are liable to be damaged if the aircraft passes through said at least one critical area.

8. The device according to claim 7, wherein the acquisition means (MQ) comprise measuring means configured to measure the electric field, the magnetic field, the electric radio waves and the magnetic radio waves, and telecommunication means configured to receive the data for measuring the electric field, the magnetic field, and the magnetic radio waves and the electric radio waves, these measurements being carried out by at least two other aircraft in the air or on the ground and/or ground stations.

9. The device according to claim 8, wherein the acquisition means (MQ) include at least one electro-optical sensor configured to measure the near peripheral electric and magnetic field.

10. The device according to claim 7, further comprising means for remote storage, in real time, of the acquired data.

11. The device according to claim 7, wherein the design means comprise at least one supervised or unsupervised deep learning machine.

12. The device according to claim 7, wherein the protection means (MP) comprise isolation means, the protection means being configured to deactivate said components and/or to activate the means for isolating said components.

13. The device according to claim 7, wherein the atmospheric disturbances comprise a lightning strike and/or an exposure to cosmic and/or ionising rays.

14. An aircraft comprising a device for preventing, in real time, risk of atmospheric disturbances (DIS) according claim 7.
